(19) United States
(12) Patent Application Publication
(10) Pub. No.: US 2014/0063771 A1
(43) Pub. Date: Mar. 6, 2014

(54) MOUNT BASE AND ELECTRONIC APPARATUS

(71) Applicant: FUJITSU LIMITED, Kawasaki-shi (JP)

(72) Inventor: MAKOTO BANDO, Inagi (JP)

(21) Appl. No.: 13/906,096

(22) Filed: May 30, 2013

(30) Foreign Application Priority Data
Aug. 28, 2012 (JP) 2012-188048

(51) Int. Cl. H05K 5/00

(52) U.S. Cl. CPC H05K 5/0017
USPC 361/809; 248/49

(57) ABSTRACT

A mount base includes: a rotary seat rotatably provided against a stand unit by a shaft member, the shaft member being fixed to the stand unit; a rotary prop that rotates along with the rotary seat; and a cable that goes through a fixing portion provided on the rotary prop and a holding portion provided on the shaft member, and connects a first electronic device attached to a tip side of the rotary prop to a second electronic device attached to the stand unit.

### CROSS-REFERENCE TO RELATED APPLICATION

This application is based upon and claims the benefit of priority of the prior Japanese Patent Application No. 2012-188048 filed on Aug. 28, 2012, the entire contents of which are incorporated herein by reference.

### FIELD

A certain aspect of the embodiments is related to a mount base and an electronic apparatus.

### BACKGROUND

Conventionally, there has been known a mount base that includes a swivel mechanism equipped with a rotary prop rotatably stood on a stand unit, and rotatably mounts an electronic apparatus, such as a display, in a horizontal direction. A feed cable and a cable for transmitting and receiving signals are connected to the electronic apparatus mounted on the stand unit of the mount base including the swivel mechanism. These cables may pass through the mount base including the swivel mechanism. For example, Japanese Laid-open Patent Publication No. 2001-16753 (hereinafter referred to as “Patent Document 1”) discloses a swivel unit housing the feed cable.

In the swivel unit disclosed by the Patent Document 1, a power receiving connector is mounted on the rear of a chassis which is a part of the stand unit. A base end of the feed cable is connected to the power receiving connector. A tip of the feed cable is inserted into a rectangular hole provided on a peripheral wall of a central recess included in the stand unit. Then, the feed cable is gently wound around a fixed shaft in the central recess according to desired winding (e.g. double winding), and forms a cable buffer zone. Then, the tip of the feed cable is inserted into a hole drilled in the vicinity of the fixed shaft of a swivel rail, and is guided to the outside of the swivel unit through a rectangular groove provided in a radial direction in an upper surface of the swivel rail.

By the way, when the cable passes through the mount base including the swivel mechanism, it is necessary to restrain slipping-out and disconnection of the cable resulting from the operation of the swivel mechanism. In the swivel unit disclosed by the above-mentioned Patent Document 1, when the swivel rail rotates, an excess length of the cable is drawn out from the doubly wound cable buffer zone. Thereby, the slipping-out and the disconnection of the cable can be restrained.

### SUMMARY

According to an aspect of the present invention, there is provided a mount base including: a rotary seat rotatably provided against a stand unit by a shaft member, the shaft member being fixed to the stand unit; a rotary prop that rotates along with the rotary seat; and a cable that goes through a fixing portion provided on the rotary prop and a holding portion provided on the shaft member, and connects a first electronic device attached to a tip side of the rotary prop to a second electronic device attached to the stand unit.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view of an electronic apparatus according to a first embodiment, as viewed from a front side thereof;

FIG. 2 is a perspective view of the electronic apparatus according to the first embodiment, as viewed from a rear side thereof;

FIG. 3 is a perspective view illustrating a state where a main body is detached from a rotary prop;

FIG. 4 is an exploded view of a stand unit and the rotary prop according to the first embodiment,

FIG. 5 is a perspective view of the electronic apparatus in a state where the main body is detached from the rotary prop, as viewed from the rear side of the electronic apparatus;

FIG. 6 is a perspective view illustrating the rotary prop attached to the stand unit, as viewed from the rear side;

FIG. 7 is a perspective view illustrating a state where a front cover and a rear cover of the rotary prop and an upper cover of the stand unit are detached, as viewed from the rear side of the rotary prop;

FIG. 8 is a perspective view illustrating a state where the front cover and the rear cover of the rotary prop and the upper cover of the stand unit are detached, as viewed from the front side of the rotary prop;

FIG. 9 is an elevation view illustrating a state where the front cover and the rear cover of the rotary prop and the upper cover of the stand unit are detached;

FIG. 10 is an enlarged sectional view taken along a line A-A in FIG. 9;

FIG. 11 is an explanatory diagram illustrating schematically a state where a rotary seat according to the first embodiment rotates;

FIG. 12A is an explanatory diagram illustrating schematically a state where a cable is placed on the rotary seat according to a comparative example;

FIG. 12B is an explanatory diagram illustrating schematically a state where the rotary seat is rotated;

FIG. 13 is an exploded view of the stand unit and the rotary prop according to a second embodiment; and

FIG. 14 is a perspective view illustrating a state where the front cover and the rear cover of the rotary prop and the upper cover of the stand unit are detached, as viewed from the front side of the rotary prop.

### DESCRIPTION OF EMBODIMENTS

Hereinafter, a description will be given of an embodiment of the present invention with reference to the drawings. It should be noted that a size and ratio of each portion do not correspond to the actual ones in some drawings. Also, component elements which exist in fact are omitted in some drawings for convenience of explanation.

### First Embodiment

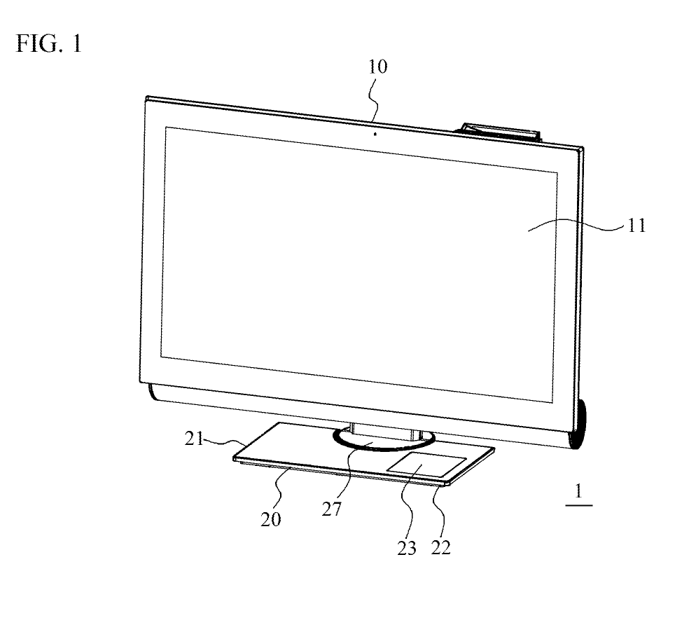

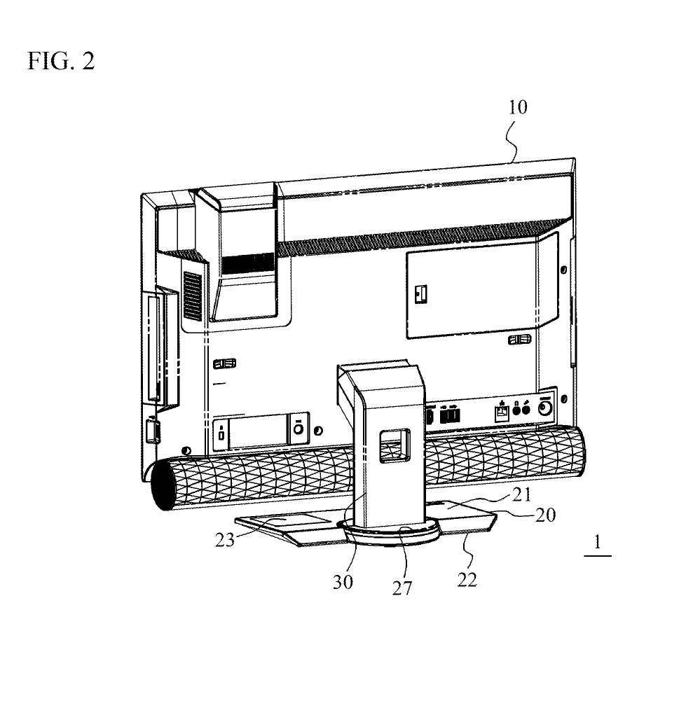

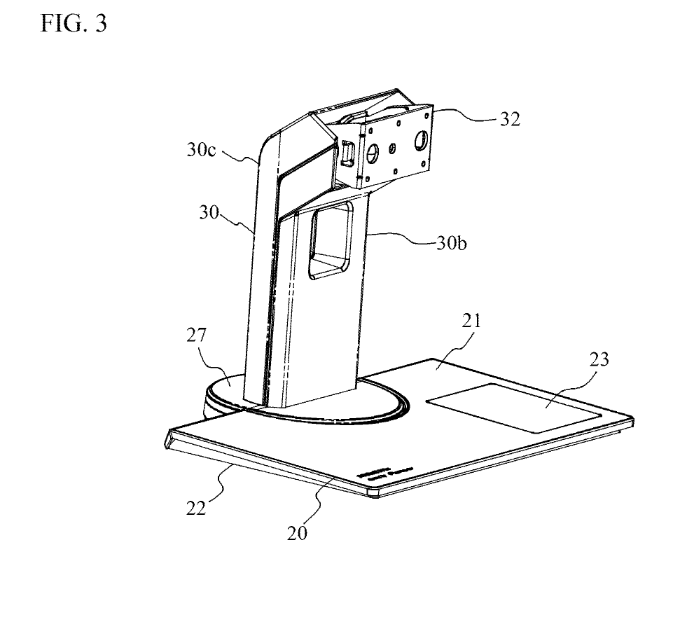

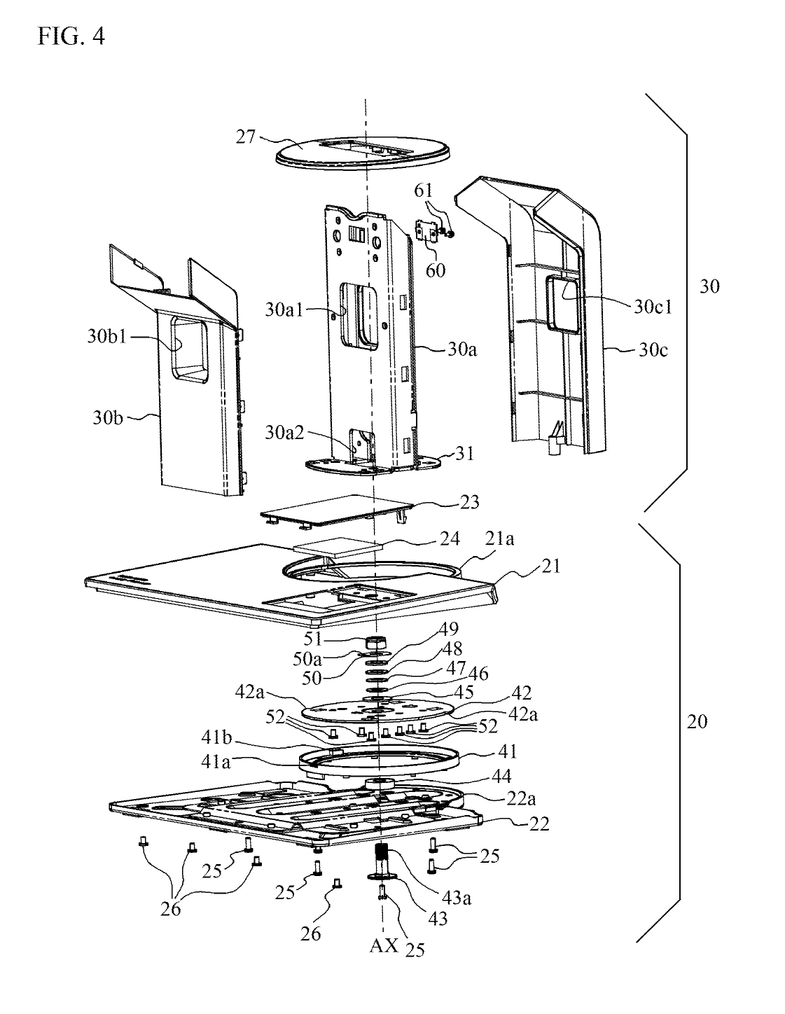

FIG. 1 is a perspective view of an electronic apparatus 1 according to a first embodiment, as viewed from a front side thereof. FIG. 2 is a perspective view of the electronic apparatus 1 according to the first embodiment, as viewed from a rear side thereof. FIG. 3 is a perspective view illustrating a state where a main body 10 is detached from a rotary prop 30. FIG. 4 is an exploded view of a stand unit 20 and the rotary prop 30.

The electronic apparatus 1 includes: the main body 10 corresponding to a first electronic device; and a NFC (Near Field Communication) main body 24 corresponding to a second electronic device. The main body 10 and the NFC main body 24 are electrically connected to each other. The main body 10 is an all-in-one PC (Personal Computer) equipped with a LCD (Liquid Crystal Display) unit 11. The main body 10 is an example of the first electronic device, and is attached to a tip side of the rotary prop 30 stood on the stand unit 20. The NFC main body 24 is installed in the stand unit 20. The NFC main body 24 is an example of the second electronic device. The NFC main body 24 is a non-contact IC card module, and is stored by the stand unit 20 so that a user can easily use the NFC main body 24. When the NFC main body 24 communicates with a communication terminal such as a card and a mobile phone, the communication terminal may be used so as to be put on the NFC main body 24. If such a usage state of the NFC main body 24 is taken into consideration, it is desirable that the NFC main body 24 is stored in a position where an upper surface of the stand unit 20 can be made flat. Here, an electronic device which may be electrically connected to the main body 10 can be employed as the second electronic device, instead of or together with the NFC main body 24. For example, a user interface, such as a USB (Universal Serial Bus) connector, a microphone, headphones, a memory card drive, a HMI (Human Machine Interface), and an optical drive can be employed as the second electronic device.

The main body 10 is electrically connected to the NFC main body 24 via a first cable 70 and a second cable 72. As long as a combination of the first electronic device and the second electronic device is a combination of electronic devices that are electrically connected to each other via the cable, it may be any kind of combination. Also, the cable may be a feed cable, and may be a cable for transmitting and receiving signals.

A detailed description will be given of the stand unit 20 and the rotary prop 30 with reference to FIG. 4. The stand unit 20 and the rotary prop 30 form a mount base including a swivel mechanism. Specifically, the stand unit 20 and the rotary prop 30 form the swivel mechanism equipped with the rotary prop 30 rotated against the stand unit 20, and serve as a mount base which attaches the main body 10 to a tip part of the rotary prop 30. The stand unit 20 includes an upper cover 21 and a base unit 22. The upper cover 21 and the base unit 22 are integrally assembled by fixing screws 25. A storage portion for the NFC main body 24 is provided on the upper cover 21, and a NFC cover 23 that covers the stored NFC main body 24 is provided.

The base unit 22 includes a rotary seat installation portion 22a. The upper cover 21 includes a frame unit 21 a at a position corresponding to the rotary seat installation portion 22a. Then, in the stand unit 20, a rotary seat 42 is rotatably provided against the base unit 22. The rotary seat 42 is mounted in the stand unit 20 by a shaft member 43 fixed to the base unit 22. The rotary seat 42 is a disciform member, and is rotatably mounted on a circular frame member 41 and a circular support member 44 which are placed on the rotary seat installation portion 22a. A cable insertion hole 41 a into which a first cable 70 described later is inserted is provided on an external wall of the frame member 41. A projection 41b is provided on the inside of the external wall of the frame member 41. The projection 41b serves as a stopper which regulates a rotation range of the rotary seat 42 by contacting a cutout portion 42a provided on an outer circumferential rim portion of the rotary seat 42.

The shaft member 43 includes a screw portion 43a in an upper end thereof, and is inserted toward an upper surface side of the base unit 22 from a lower surface side thereof. Specifically, the shaft member 43 penetrates the circular support member 44 arranged between the rotary seat 42 and the base unit 22. The shaft member 43 is inserted so that the screw portion 43a is exposed from a upper surface of the rotary seat 42 placed on the support member 44. Washers 45 to 48 are fitted in the screw portion 43a exposed from the upper surface of the rotary seat 42, and a D-type washer 49 is further fitted on the washer 48. Then, a laminated cable guide board 50 is fitted on an upper side of the D-type washer 49. The cable guide board 50 includes a cable insertion hole 50a. A nut 51 is put on the cable guide board 50 and is fastened. Thereby, the rotary seat 42 is rotatably mounted on the stand unit 20, more specifically, the base unit 22. Here, the shaft member 43 is fixed to the stand unit 20, and is not rotated. Then, the cable guide board 50 fastened with the nut 51 so as to be united with the shaft member 43 forms a holding portion H2 of the first cable 70.

Thus, the rotary prop 30 is mounted on the rotary seat 42 which is rotatably provided against the base unit 22. The rotary prop 30 includes a prop body 30a, and a front cover 30b and a rear cover 30c which cover the prop body 30a. A disk-shaped attachment unit 31 is formed in the bottom of the prop body 30a. The attachment unit 31 contacts the upper surface of the rotary seat 42 and is attached to the rotary seat 42 by fixing screws 52. Thereby, the prop body 30a is united with the rotary seat 42 and rotates along with the rotary seat 42.

A relay substrate 60 is mounted on the prop body 30a by fixing screws 61. The first cable 70 extending from the NFC main body 24 and a second cable 72 extending from the main body 10 are connected to the relay substrate 60. That is, the NFC main body 24 and the main body 10 are connected to each other via the first cable 70, the relay substrate 60 and the second cable 72.

The front cover 30b and the rear cover 30c are attached to such a prop body 30a. The prop body 30a includes a window portion 30a1. In response to this, the front cover 30b includes a window portion 30b1, and the rear cover 30c includes a window portion 30c1. A rotary seat cover 27 that covers the rotary seat 42 is mounted on a base end of the rotary prop 30. Here, in the present embodiment, the rotary prop 30 and the rotary seat 42 are prepared as separate components, but the rotary prop 30 (i.e., the prop body 30a) and the rotary seat 42 may be integrally formed with each other.

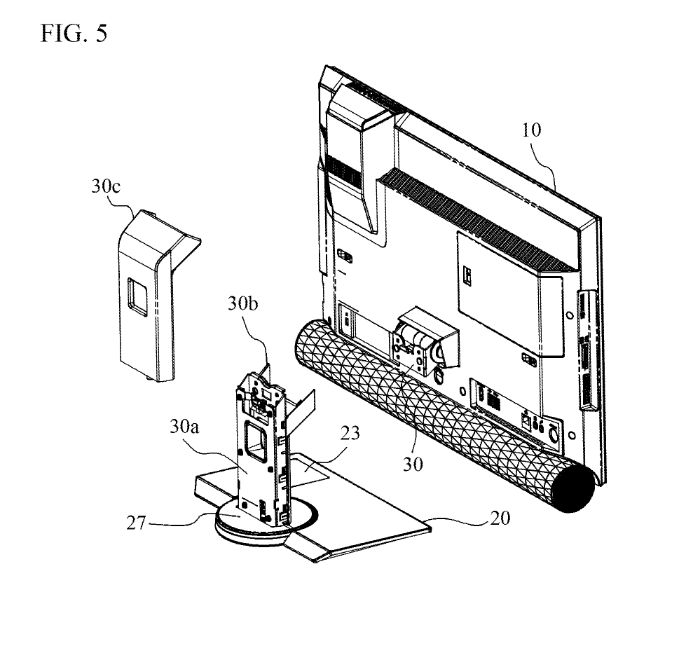

With reference to FIGS. 3 and 5, a hinge unit 32 intervenes between the main body 10 and the tip side of the rotary prop 30. The hinge unit 32 includes a tilt mechanism and can swing the main body 10 in up-and-down directions against the rotary prop 30.

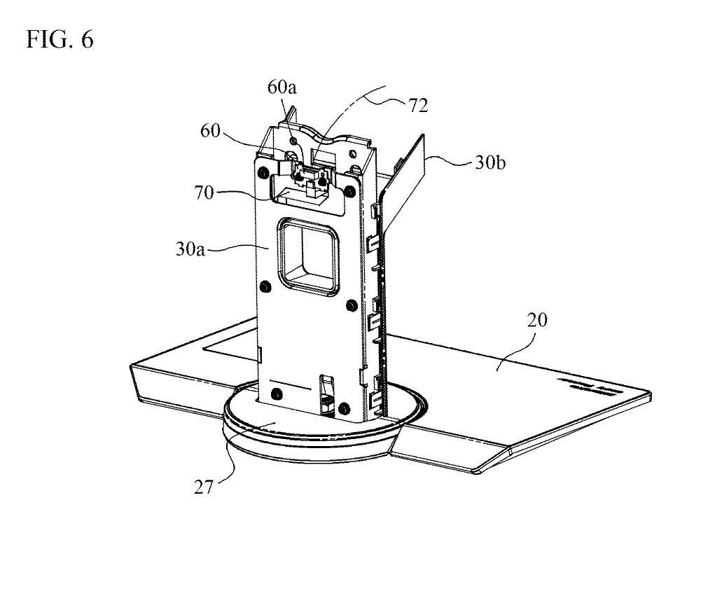

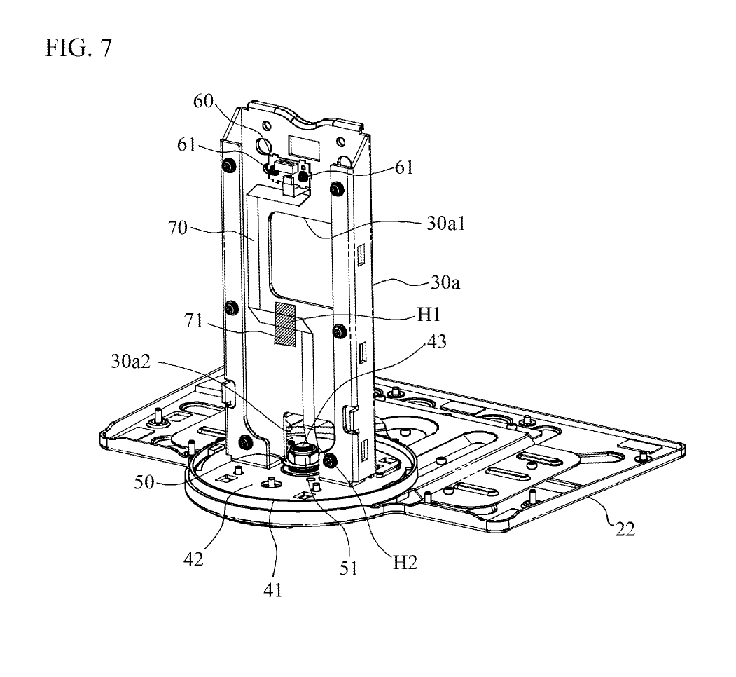

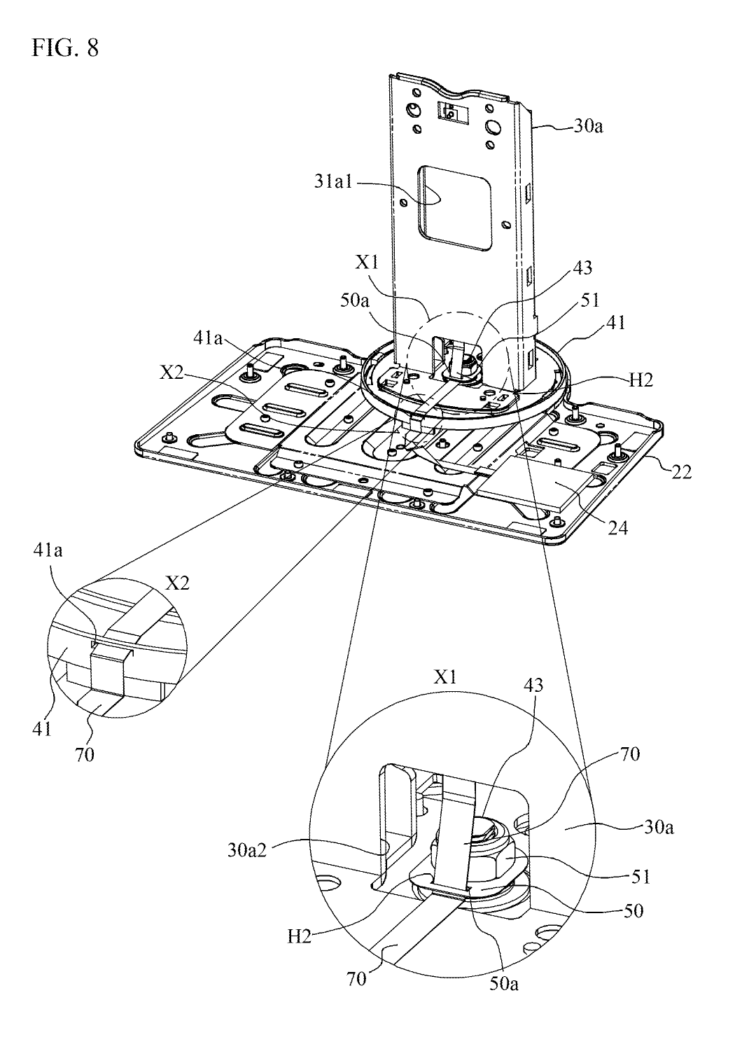

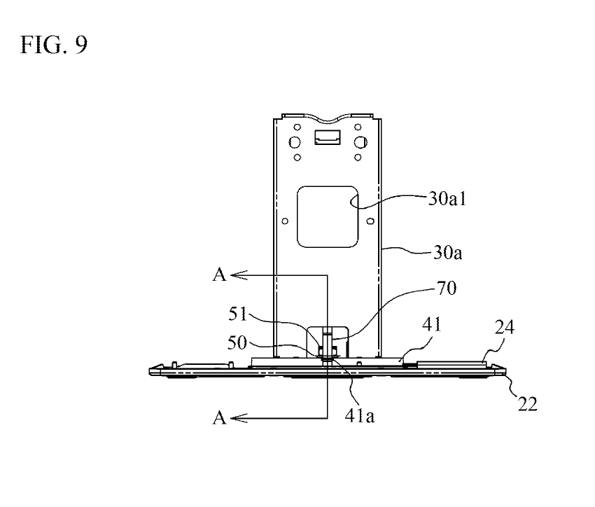

With reference to FIGS. 6 to 8, the first cable 70 is arranged in the rotary prop 30. The first cable 70 is a flat cable, and is arbitrarily folded and arranged so as to avoid the window portion 30a1. With reference to FIG. 8, one end of the first cable 70 is connected to the NFC main body 24. Then, the first cable 70 is inserted into a cable insertion hole 41a provided on the frame member 41, as illustrated by an enlarged domain X2 in FIG. 8. Then, the first cable 70 is inserted into the cable insertion hole 50a which the cable guide board 50 provided on the shaft member 43 includes, as illustrated by an enlarged domain X1 in FIG. 8. Then, as illustrate in FIG. 7, the first cable 70 passes through a cutout portion 30a2 provided on the prop body 30a, is drawn into a rear surface side of the prop body 30a, and is extended upwardly along the prop body 30a. In addition, the first cable 70 is fixed with a tape 71 at a fixing portion H1 under the window portion 30a1. The first cable 70 is folded so as to avoid the window portion 30a1 at an upper side than the fixing portion H1, and another end of the first cable 70 is connected to the relay substrate 60.

Here, the rotary prop 30 of the first embodiment includes the window portion 30a1 from a viewpoint of weight saving or appearance design. When the rotary prop 30 does not include the window portion 30a1, the fixing portion H1 may be provided further upward. The relay substrate 60 can also serve as the fixing portion H1. It is desirable that the fixing portion H1 is provided at a position as high as possible since the tolerance to the twist of the first cable 70 resulting from the rotation of the rotary prop 30 becomes large.

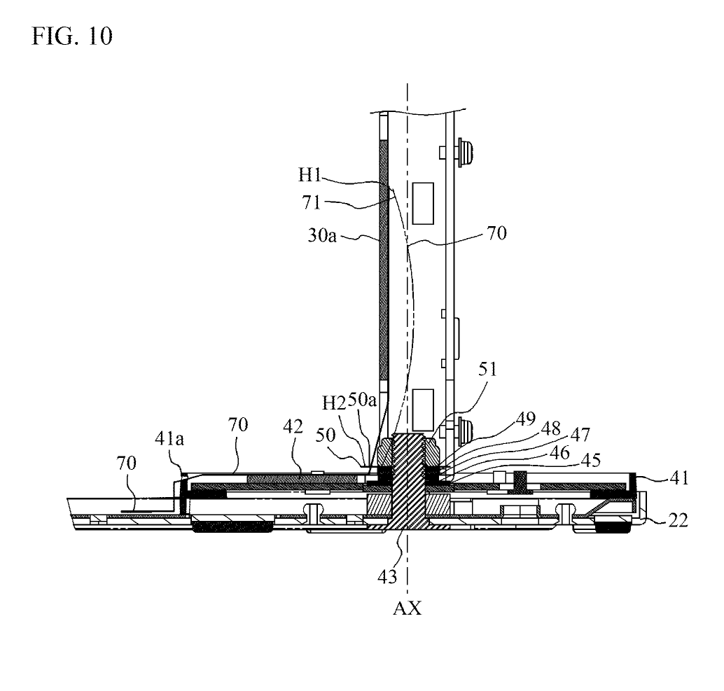

Next, a description will be given of a rotation center axis AX of the rotary prop 30. With reference to FIG. 4, a center axis of the shaft member 43 becomes the rotation center axis AX of the rotary seat 42, and is also identical with the rotation center axis AX of the rotary prop 30. The rotary prop 30 includes the rotation axis of the rotary seat 42, and is stood on the rotary seat 42. That is, in a projected diagram in which the rotary prop has been seen from above or from below, the rotation center axis AX of the rotary seat 42 is included in a projection domain of the projected diagram. With reference to FIG. 10, the rotation center axis AX of the rotary seat 42 passes through the rotary prop 30. Then, the rotary prop 30 includes the rotation axis of the rotary seat 42, and is stood on the rotary seat 42.

It is desirable that the fixing portion H1 is provided at a position near the rotation center axis AX as much as possible. The fixing portion H1 is provided at the position near the rotation center axis AX, so that haul resulting from rotation of the rotary prop 30 can be restrained, and the first cable 70 can be smoothly twisted between the fixing portion H1 and the holding portion H2. When the rotary prop 30 includes the rotation axis of the rotary seat 42, and is stood on the rotary seat 42, it becomes easy to place the fixing portion H1 near the rotation center axis AX.

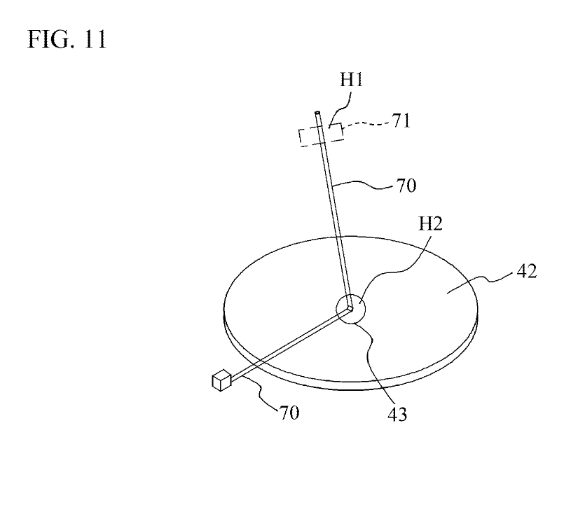

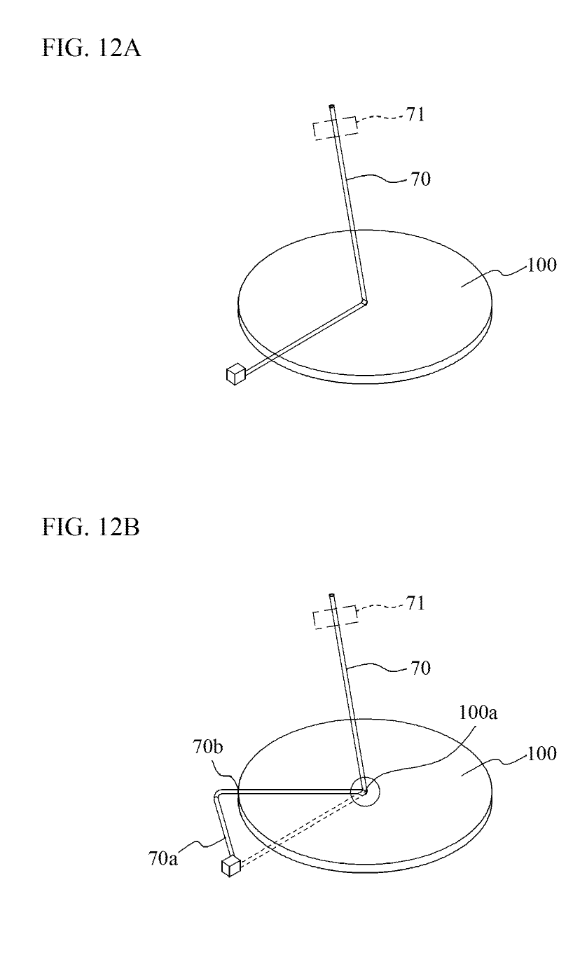

A detailed description will be given of a situation of the first cable 70 when the mount base including the swivel mechanism of the first embodiment operates, together with the situation of the first cable 70 when the swivel mechanism of the comparative example operates, with reference to FIGS. 11 and 12. The swivel mechanism of the first embodiment illustrated in FIG. 11 includes the shaft member 43 that is placed at the center of the rotary seat 42. The first cable 70 is held by the holding portion H2 provided on the shaft member 43. Thus, the first cable 70 is not held by and fixed to the rotary seat 42. Therefore, the first cable 70 is not affected by the rotation of the rotary seat 42. Also, the first cable 70 is fixed to the fixing portion H1 provided above the holding portion H2. Therefore, when the rotary prop 30 rotates along with the rotary seat 42, the first cable 70 is twisted between the fixing portion H1 and the holding portion H2. Thus, the swivel mechanism of the first embodiment can achieve the rotation of the rotary prop 30 without including the excess length of the cable.

On the other hand, in the swivel mechanism of the comparative example as illustrated in FIGS. 12A and 12B, the first cable 70 is fixed to the holding portion H2 and a fixing portion H3 on a rotary seat 100. Therefore, when the rotary seat 100 rotates, the first cable 70 is drawn out according to a rotation angle of the rotary seat 100, and hence an excess length 70a of the first cable is needed. However, when the first cable includes the excess length 70a, the excess length 70a causes the rubbing of the first cable 70 and the occurrence of the abnormal noise. Moreover, it is necessary to take the measure for storing the excess length 70a, such as forming the cable buffer zone.

Thus, according to the mount base including the swivel mechanism of the first embodiment, the first cable 70 can eliminate the power of the haul and the compression as much as possible. Moreover, since the excess length 70a of the first cable 70 is unnecessary, the slipping-out from a connector resulting from a friction between the first cable 70 and the housing, and the occurrence of the abnormal noise by the rubbing can be restrained. According to the mount base including the swivel mechanism of the first embodiment, the haul and the compression of the cable is restrained, cables with various forms, including a flat cable, can be employed.

Moreover, since forming the cable buffer zone is unnecessary, the cable forming becomes simple and the assembly process can be reduced. Even after the assembly of the mount base, a user can easily check the normal operation. Also, according to the mount base including the swivel mechanism of the first embodiment, the excess length 70a of the first cable 70 is unnecessary. Therefore, even when the rotation angle of the swivel mechanism becomes large, the cable length does not increase. As a result, the cost rise and the signal degradation resulting from the increment of the cable length can be restrained.

### Second Embodiment

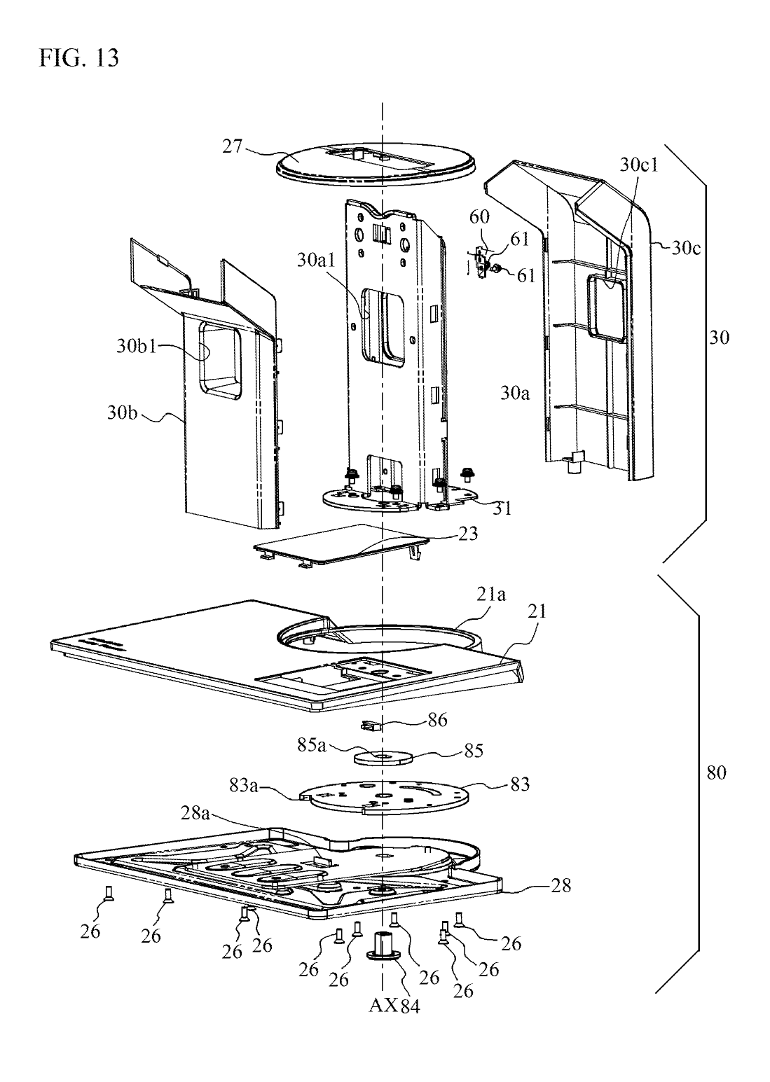

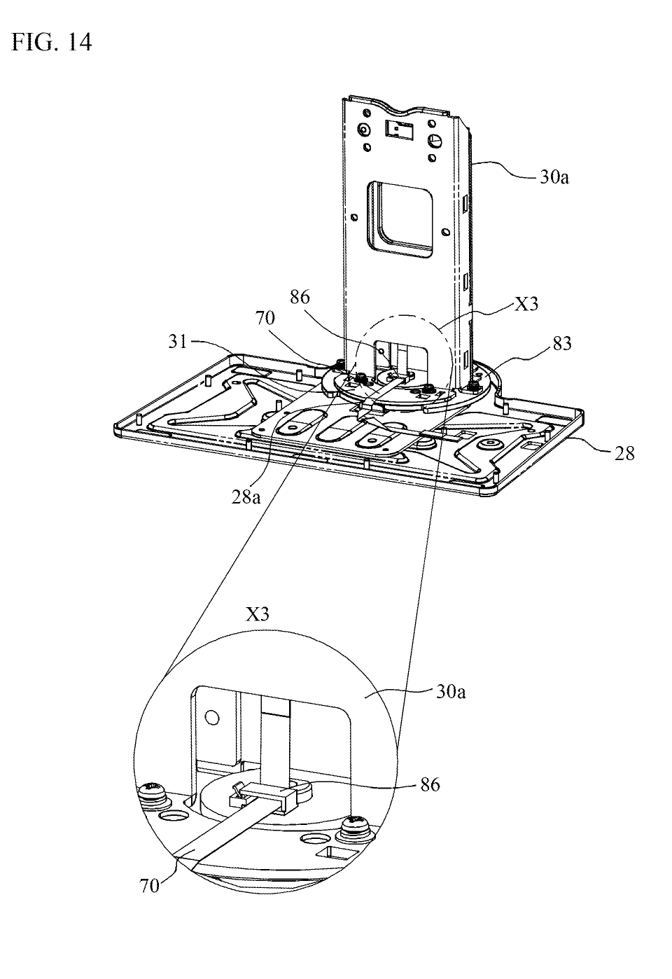

Next, a description will be given of a second embodiment, with reference to FIGS. 13 and 14. FIG. 13 is an exploded view of the stand unit and the rotary prop according to a second embodiment. FIG. 14 is a perspective view illustrating a state where the front cover and the rear cover of the rotary prop and the upper cover of the stand unit are detached, as viewed from the front side of the rotary prop. The second embodiment is different from the first embodiment in that the shaft member 43 including the screw portion 43a is used in the first embodiment and a shaft member 84 to be fixed by caulking is used in the second embodiment. Hereinafter, the difference between the first embodiment and the second embodiment is mainly explained. Component elements corresponding to those of the first embodiment are designated by identical reference numerals, and a detailed description thereof is omitted.

In the second embodiment, the stand unit includes a base unit 28 instead of the base unit 22 of the first embodiment. A projection 28a is provided on the base unit 28. The projection 28a serves as a stopper which regulates a rotation range of a rotary seat 83 by contacting a cutout portion 83a provided on an outer circumferential rim portion of the rotary seat 83.

A clasp 85 is placed on an upper surface of the rotary seat 83. An insertion hole 85a is provided on the clasp 85, and the shaft member 84 is inserted from a lower surface side of the base unit 28. The shaft member 84 passes through the rotary seat 83 and the clasp 85, and a top of the shaft member 84 projects from an upper surface of the clasp 85. Then, the top of the shaft member 84 is caulked and is united with the clasp 85, so that the rotary seat 83 is rotatably attached. Here, the clasp 85 does not rotate. A clamp 86 is placed on the upper surface of the clasp 85. The clamp 86 holds the first cable 70. That is, the clamp 86 is provided instead of the cable guide board 50 of the first embodiment, and forms the holding portion. As long as a member for forming the holding portion can hold the cable, the form of the member is not limited. For example, the member may hold the cable with a tape.

Thus, even when the shaft member is fixed by caulking, the first electronic device and the second electronic device can be connected to each other with the cable which goes through the holding portion and the fixing portion. Thereby, the excess length of the cable can be made unnecessary as with the first embodiment.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various change, substitutions, and alterations could be made hereto without departing from the spirit and scope of the invention.

What is claimed is:

1. A mount base comprising:
a rotary seat rotatably provided against a stand unit by a shaft member, the shaft member being fixed to the stand unit;
a rotary prop that rotates along with the rotary seat; and
a cable that goes through a fixing portion provided on the rotary prop and a holding portion provided on the shaft member, and connects a first electronic device attached to a tip side of the rotary prop to a second electronic device attached to the stand unit.

2. The mount base as claimed in claim 1, wherein the rotary prop includes a rotation axis of the rotary seat, and is stood on the rotary seat.

3. An electronic apparatus comprising:
a rotary seat that is rotatably provided against a stand unit by a shaft member, the shaft member being fixed to the stand unit;
a rotary prop that rotates along with the rotary seat;
a first electronic device attached to a tip side of the rotary prop;
a second electronic device attached to the stand unit; and
a cable that goes through a fixing portion provided on the rotary prop and a holding portion provided on the shaft member, and connects the first electronic device to the second electronic device.
